(19) United States
(12) Patent Application Publication
(10) Pub. No.: US 2005/0133081 A1
(43) Pub. Date: Jun. 23, 2005

(54) Photo voltaic solar cells integrated with mosfet

(75) Inventors: Michael Amato, Newburyport, MA (US); Nestore Polce, Chelmsford, MA (US); Nathan Zommer, Los Altos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: IXYS Corporation, Santa Clara, CA (US)

(21) Appl. No.: 10/994,172

(22) Filed: Nov. 19, 2004

Related U.S. Application Data
(60) Provisional application No. 60/525,553, filed on Nov. 25, 2003.

(51) Int. Cl. H01L 31/119; H01L 31/113; H01L 31/062; H01L 31/00

(52) U.S. Cl. 136/244; 136/251

(57) ABSTRACT

A photovoltaic (PV) device comprising a silicon-on-insulator (SOI) substrate including a first substrate, a second substrate, and an insulating layer provided between the first and second substrates; a plurality of tubs defined using the first substrate, each tub being isolated from an adjacent tub using the insulation layer and an isolation structure; a first PV array including a plurality of PV cells to generate a first voltage when light is shined on the first PV array; a second PV array including a plurality of PV cells to generate a second voltage when the light is shined on the second PV array; a transistor defined on one of the tubs and coupled to the first and second PV arrays, wherein the first PV array is configured to provide a given voltage to the transistor when the second PV array is generating the second voltage.

### CROSS REFERENCES TO RELATED APPLICATIONS

The present application claims priority from U.S. Provisional Patent Application No. 60/525,553, filed on Nov. 25, 2003, which is incorporated by reference.

### BACKGROUND OF THE INVENTION

The present invention relates to solar cells, in particularly a discrete semiconductor device including solar cells that are integrated with a transistor.

State of the art high efficiency photovoltaic (“PV”) solar cells have been introduced as a component in a die (chip) or wafer. A typical solar cell producer uses semiconductor manufacturing processes that are specialized to produce the PV solar cells. The same producer sells the solar cells in the form of chips or wafers. Each solar cell is formed on a single chip or wafer. The buyer of these cells then assembles them in large panels in a series or series-and-parallel combination to produce a higher output power than is possible from one monolithic solar cell.

A solar cell, in its basic form, is a p/n junction (a diode) that generates 0.4 to 0.7 volt when light shines on it. The high efficiency cells produce the higher voltage range, which is about 0.65 to 0.7 volt. Accordingly, a user of these cells generally has to connect them in series to generate a higher, more useful voltage. A plurality of such solar cell arrays are connected in parallel to produce higher output current, thereby generating higher electrical power.

For a six-volt output, 10 PV cells are generally connected in series. Each chip has to be isolated from each other and connected in a scheme, as shown in FIG. 1A, where solar cells PV1 to PV10 are connected in series. The potential of a node 1 is about 6 volts above that of a node 20.

FIG. 1B shows a die bonding and mounting on a substrate 80, where the PV chips are 41-50, representing 10 PV cells, are connected in series. FIG. 1B illustrates a component configuration corresponding to FIG. 1A. The connections are done via conducting wires 61-71. The dice are mounted on conductor pads 21-30. As shown, many additional components (e.g., the connecting wires, conductor pads, and substrate) are needed to place the solar cells in series and obtain a higher voltage output. This results in increased material and labor costs, as explained in U.S. patent application No. 10/958,698, filed on Oct. 4, 2004, entitled “DISCRETE AND INTEGRATED PHOTO VOLTAIC SOLAR CELLS,” which is assigned to the assignee of the present application and is incorporated by reference.

One proposed solution has been to use a dielectric isolation (DI) technology. This technology provides a monolithic chip or substrate having a higher voltage output without using connecting wires, conductor pads, and other external components. The DI technology may be used to provide a monolithic substrate having a plurality of solar cells. At first, a photoresist layer is provided on a front side of a silicon substrate. The photoresist is patterned and etched to expose certain parts of the silicon substrate. The exposed parts are etched to form a plurality of grooves on the substrate. The photoresist is then removed.

The substrate is doped with impurities to form a buried layer. An oxide layer is formed on the buried layer. A polysilicon layer is deposited on the oxide layer to a thickness of 500 microns or more. The substrate is then flipped over and grinded to remove excess portions of silicon on the backside.

The DI technology requires deposition of a thick layer of polysilicon and then mechanical coarse grinding techniques, which is both costly and results in a high degree of defects. Also, it is difficult to make a small-sized solar cell devices using the DI technology due to its coarse grinding step.

### BRIEF SUMMARY OF THE INVENTION

The present invention relates to a photo voltaic (PV) device having a plurality of PV solar cells integrated with at least one transistor, e.g., MOSFET. The PV device is formed on a single or monolithic semiconductor substrate. The output voltage of the PV device may be customized to a desired level by appropriately connecting a given number of the PV cells in series during fabrication steps of the PV device. Similarly, the output current is also customized to a desired level by appropriately connecting the PV cells in parallel during the fabrication of the PV device. These series and parallel connections are obtained by patterning the interconnect (or metal) layer that is deposited on top of the solar cells.

By using microelectronic techniques disclosed herein, a smaller-sized PV device that outputs a relatively high voltage (e.g., 3-6 volts) is obtained. In the present embodiment, a relatively small die-sized PV device can be packaged in a simple package, like the ones used in discrete semiconductor devices, e.g., LEDs, transistor, diodes etc., with a transparent plastic encapsulation.

As used herein, a packaged device including a PV die is referred to as a “packaged PV device.” The packaged PV device is a discrete device that includes one or more PV dice that share a common package. One or more semiconductor devices or components (e.g., LED, transistor, capacitor, charge pump, diode, etc.) may also be included in the same package with the solar cells. The semiconductor component may be integrated with the solar cells on a monolithic substrate or wire-bonded (or otherwise connected) to the monolithic substrate. As used herein, a “PV device” generally refers to a component including at least one die having one or more PV cells, but may also be used to refer to a packaged PV device. The terms “PV cell” and “solar cell” are used interchangeably and refer to a component that is able to generate a current or voltage when exposed to visible light (not limited to sunlight) or other electromagnetic radiation.

In one embodiment, a packaged PV device has a plurality of pins, e.g., two pins, and can be used as a discrete component in a desired circuit or product. Such a discrete product (or a single packaged product) contains one or more small, packaged PV devices with high voltage outputs. Each PV device or die generates about 0.6 to 0.7 volt of output. The discrete product enables the operation of portable electronic devices with off-line battery chargers, namely using light energy to charge the battery. With the use of such a discrete product, wireless electronic devices or instruments may be mounted virtually anywhere and operated without a fixed power line. These electronic devices can be powered using solar energy using the high efficiency PV devices described herein.

Modem IC's often requires very low operating or quiescent currents, which the present PV devices can power by charging the battery or energy storage capacitors in the IC's as part of an electronic device. The present PV device of the present invention may be used in various electronic devices, e.g., remote sensors, which are wireless and free of the need to be connected to a power line. Also, the PV dice themselves can be used as part of batteries to trickle charge the batteries internally if a PV device is implemented as part of the battery. To charge the batteries, a PV device of the desired voltage needs to be selected. For 1.5 volt batteries, a PV device having 3 PV cells that are integrated to provide about 1.8 volt is needed in the present implementation. The number of PV cells that need to be connected in series depends on the voltage output desired for a PV device.

In one embodiment, a photovoltaic (PV) cell device comprises a first semiconductor substrate; a second semiconductor substrate bonded to the first semiconductor substrate; an insulating layer provided between the first and second substrates to electrically isolate the first substrate from the second substrate; a plurality of PV cells defined on the first substrate, each PV cell including a n-type region and a p-type region; a plurality of vertical trenches provided in the first substrate to separated the PV cells, the vertical trenches terminating at the insulating layer; a plurality of isolation structures provided within the vertical trenches, each isolation structure including a first isolation layer including oxide and a second isolation layer including polysilicon; and an interconnect layer patterned to connect the PV cells to provide X number of PV cells in series and Y number of PV cells in parallel. The n-type regions are formed by performing ion implantation of arsenic to provide shallow junction depths for the n-type regions, so that PV cell device is optimized for sunlight. Each trench has an opening whose width is greater than 5,000 angstroms. Each trench may have a width of about 2 microns or more, or about 3 microns or more.

In another embodiment, a photovoltaic (PV) device comprising a silicon-on-insulator (SOI) substrate including a first substrate, a second substrate, and an insulating layer provided between the first and second substrates; a plurality of tubs defined using the first substrate, each tub being isolated from an adjacent tub using the insulation layer and an isolation structure; a first PV array including a plurality of PV cells to generate a first voltage when light is shined on the first PV array; a second PV array including a plurality of PV cells to generate a second voltage when the light is shined on the second PV array; a transistor defined on one of the tubs and coupled to the first and second PV arrays, wherein the first PV array is configured to provide a turn-on voltage to the transistor when the second PV array is generating the second voltage. The device includes no more than two leads extending outwardly from a package of the device. The device includes no more than six leads extending outwardly from the package of the device.

In another embodiment, a packaged photovoltaic (PV) device includes a structure including a first substrate, a second substrate, and an insulating layer provided between the first and second substrates; a plurality of tubs defined using the first substrate, each tub being isolated from an adjacent tub using the insulation layer and an isolation structure extending orthogonal to the insulation layer; a first PV array including a plurality of PV cells to generate a first voltage when the light is shined on the first PV array; a component defined on at least one tub and coupled to the first PV array, the component including a first node coupled to the first PV array and a second node configured to be coupled to a load; and a packaged enclosing the first PV array and the component, wherein the component is configured to be turned on when the first PV array is generating the first voltage, so that the generated first voltage can be transferred from the first node to the second node, wherein each PV cell of the first PV array is defined in a corresponding one of the plurality of tubs.

In another embodiment, a method for forming a photovoltaic (PV) device includes providing a structure including a first substrate, a second substrate, and an insulating layer provided between the first and second substrates; forming a plurality of tubs using the first substrate, each tub being isolated from an adjacent tub using the insulation layer and an isolation structure extending orthogonal to the insulation layer; forming a first PV array including a plurality of PV cells to generate a first voltage when light is shined on the first PV array; forming a second PV array including a plurality of PV cells to generate a second voltage when the light is shined on the second PV array; forming a transistor defined on at least one tub and coupled to the first and second PV arrays; and enclosing the first and second PV arrays and the transistor in a package.

### BRIEF DESCRIPTION OF THE DRAWINGS

FIG. 1A illustrates a circuit diagram of a plurality of PV cells in a series connection.

FIG. 1B illustrates a plurality of PV cells connected in series using a conventional wiring connection method.

FIG. 2 illustrates a cross-sectional view of PV device according to one embodiment of the present invention.

FIG. 3 illustrates a process of forming a PV device according to one embodiment of the present invention.

FIG. 4A illustrates a plurality of solar cells coupled to a load via a switch.

FIG. 4B illustrates a cross-sectional view a PV device having a plurality of solar cells integrated with a transistor according to one embodiment of the present invention.

FIG. 5 illustrates a cross-sectional view a PV device having a plurality of solar cells integrated with a transistor according to another embodiment of the present invention.

FIG. 6 illustrates a circuit diagram of a PV device having a plurality of solar cells and a transistor formed on a monolithic substrate according to one embodiment of the present invention.

FIG. 7 illustrates a circuit diagram of a PV device having a plurality of solar cells, a transistor, and a charge pump formed on a monolithic substrate according to one embodiment of the present invention.

FIG. 8 illustrates a charge pump that may be used in a PV device according to one embodiment of the present invention.

FIG. 9 illustrates a PV device having a plurality of output nodes according to one embodiment of the present invention.

FIG. 10A illustrates a solar cell module having a lens according to one embodiment of the present invention.

FIG. 10B illustrates a solar cell module having a lens according to another embodiment of the present invention.

FIG. 10C illustrates a solar cell module having a lens according to yet another embodiment of the present invention.

FIG. 10D illustrates yet another feature of the invention, where a PV die and an LED die are packaged within in an LED package.

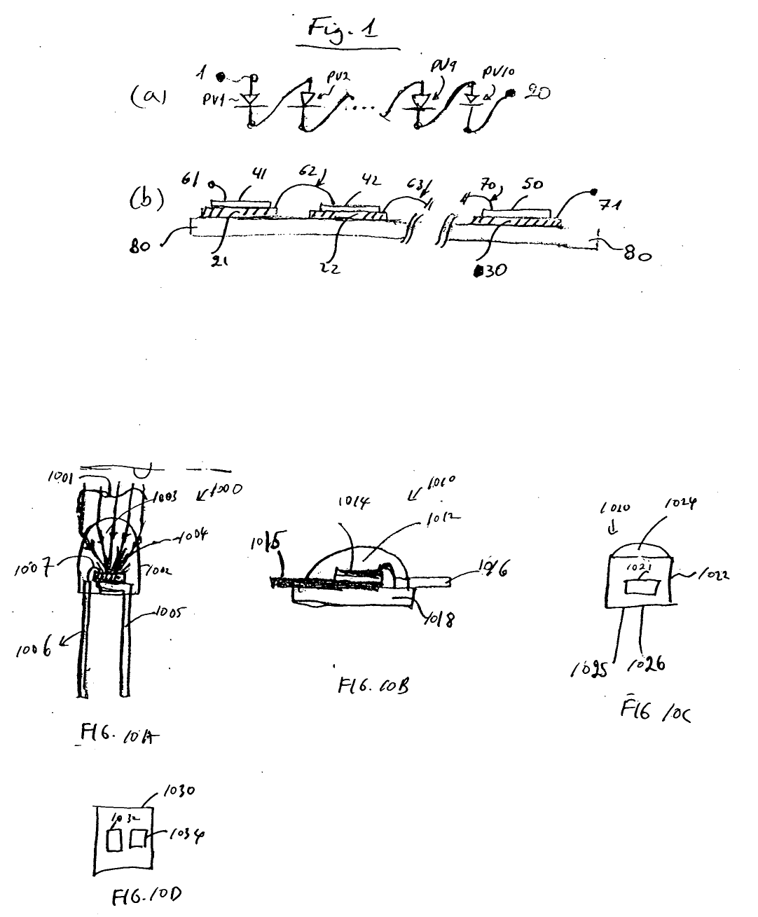

### DETAILED DESCRIPTION OF THE INVENTION

The present invention relates to photo voltaic (PV) devices having solar cells formed on a monolithic substrate, e.g., silicon substrate or crystal. FIG. 2 illustrates a cross-sectional view of a discrete PV device or die 400 according to one embodiment. The PV device 100 is formed on an SOI (Silicon on Insulator) substrate to fabricate high efficiency PV cell arrays on a single semiconductor die. The die is packaged as a single discrete device.

The PV device 400 includes a plurality of tubs or cells 402, 404, and 406. The tubs are formed on a first silicon substrate 412 that overlies an oxide layer 414. A second silicon substrate (not shown) is provided below the oxide layer. The PV device 400 is made on a wafer bonded structure or SOI structure in the present implementation but other types of substrate may also be used.

Each tub is a PV or solar cell, which is a type of pn junction diode that generates electrical current when visible light or other electromagnetic radiation is shined thereon or photons are directed toward the surface thereof. The bodies of the tubs are p-type regions 416, 418, and 420. These regions have dopant concentration of about 4 e14 to 7 e14 Boron, and maybe referred to as p− regions. N-type regions 422, 424, and 426 are formed on the upper side of the p-type regions. These have dopant concentration of >5 e19 Arsenic and may be referred to n+ or emitter regions and can be adjusted both in junction depth and resistivity to be optimized for different wavelengths of light.

For example, in one implementation, the n+ regions are formed using ion implantation of arsenic to provide shallow junction depth of about 1 micron or less. The junction depth preferably should be no more than 2 microns deep to minimize photon recombination therein and provide highly efficient PV cells. The junction depth in question and the tub depth are configured for optimal performance under sunlight and fluorescent light.

A metal interconnect 432 connects the tubs 402, 404, and 406 in series to obtain a high voltage output. The metal interconnect is formed by depositing a metal layer, e.g., aluminum, and then etching it to obtain a desired connection pattern. The metal layer can be patterned to obtain a desired number of tubs in series connection to provide a desired voltage output. Similarly, the metal layer may be patterned to obtain a desired number of tubs in parallel connection to provide a desired level of current output.

The silicon tubs are separated by isolation structures 442 formed within a plurality of trenches. Each trench has an opening whose width is greater than 5,000 angstroms, or at least 2 microns. In one implementation, the width of the opening is about 3 microns or more. The trenches are vertically (anisotropically) etched in the present embodiment, but may be sloped in other applications.

The sidewalls of the trenches are doped to provide gettering sites 444. A silicon dioxide layer 446 is formed on the gettering sites. Undoped polysilicon is deposited in the trenches and chemically mechanically polished (CMP) to form polysilicon plugs 448 that are used to fill the trenches. In the present implementation, polysilicon plugs are used to reduce the stress on the structure that may otherwise be too great if an oxide plug or the like is used due to a relatively large width of the trench.

In addition to the isolation structures 442, the tubs 402, 404, and 406 are electrically isolated from each other by forming them on the oxide layer 414 that has been previously formed to bond the first and second substrates according to the SOI technology.

Using the above SOI technology, the resultant die can be scaled up for higher current by incorporating a larger PV diode area for more current output and more PV isolated elements in series for more voltage output. By using silicon substrates that are high quality single crystal silicon, the PV elements produce electrical power at higher efficiency than the DI technology.

Another advantage to the PV device based on SOI technology is derived from utilization of a vertical (anisotropic) etch technology. The resultant vertical trenches enables formation of tubs having a greater 3D volumetric tub area for a given diode size, particularly when compared to a PV device obtained using the DI technology. This is because the DI technology generally uses KOH etching, which is isotropic in nature, to form the trench. As a result sloping sidewalls are obtained in the DI technology.

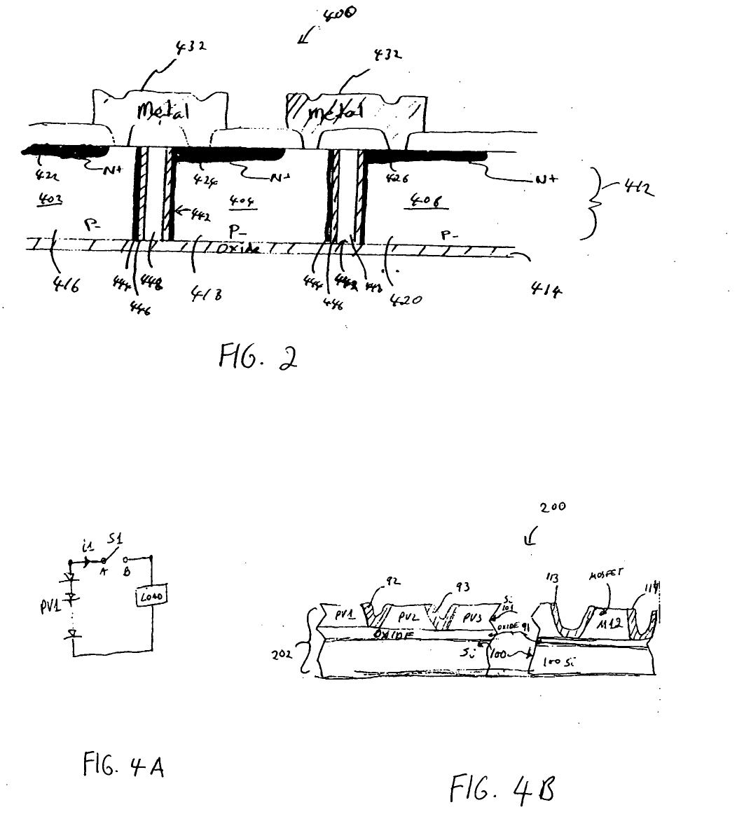

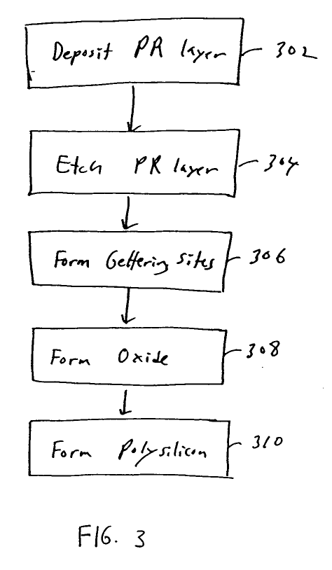

As explained above, the PV devices are formed on a SOI or wafer bonded structure (WBS) in the present implementation. A plurality of PV devices defined on the WBS are then cut into a plurality PV dice. FIG. 3 shows a process flow of making the PV devices. A photoresist layer is deposited on the upper side of the WBS 200 and patterned to expose certain areas of the first substrate 101 (step 302). The exposed areas are etched to form a plurality of trenches (step 304). These trenches are used to isolate the tubs or active regions whereon the PV solar cells are formed. The trenches are provided with a width of about 3 microns to ensure the isolation between adjacent PV cells. The trench sidewalls are doped to provide internal gettering sites for material defects and impurities (step 306). A silicon dioxide layer is deposited or thermally grown on the trench sidewalls whereon the gettering sites have been formed (step 308). The silicon dioxide layer preferably is at least about 3000 angstroms thick. An undoped polysilicon layer is formed over the silicon dioxide to fill the trenches (step 310). The oxide alone is not used to completely fill the trenches since it is relatively high in stress. As the thickness of the oxide deposited on the silicon substrate increases, the stress on the silicon increases as well. For example, an oxide that is greater than about 5000 angstroms in thickness may cause a mechanical failure and damage the crystalline structure of the underlying silicon. That is, a mechanical slip is caused by the high stress resulting from the thick oxide. To prevent such an occurrence, polysilicon that exerts less stress on the silicon is used in conjunction with the oxide to fill the trenches and act as an insulating material that isolates adjacent tubs.

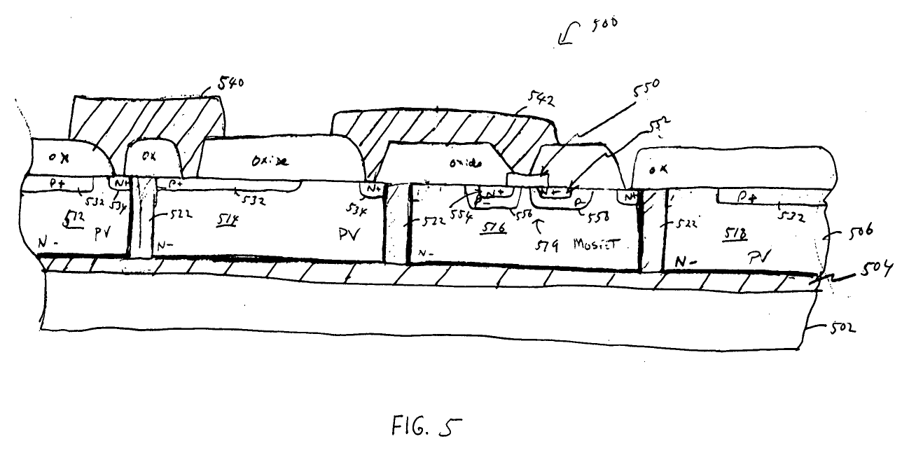

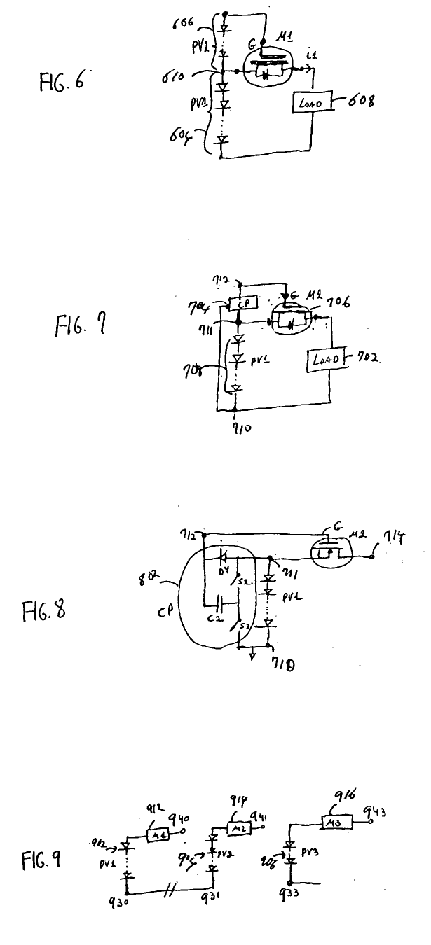

FIG. 4A illustrates a plurality of solar cells (or PV array) coupled to a load via a switch SI. The switch SI or diode is provided to prevent the back flow of current or electrical energy discharge from the load to the PV array. The load includes batteries, capacitor or other types of energy storage devices. If there is no light, or the voltage of the load is higher than the output voltage of the PV array, then the switch or diode will prevent the discharge. This switch or diode are an additional device that is added to the PV array. It is thus desirable to provide a monolithic chip, as a single PV die that provides higher voltage output and has a switch or diode integrated in it as part of the die in a single monolithic chip. In the present implementation, the switch is a MOSFET which has a lower voltage drop across it than a diode. For example, the potential drop associated with the MOSFET may be in microvolts rather than 0.3-0.6 volt associated with the diode. The MOSFET acts as a synchronous rectifier (“SR”) as described in the following paragraphs. A bipolar transistor or SCR may also be used in place of a MOSFET.

One issue associated with using MOSFET is the necessity for providing a gate turn-on voltage to turn it on when light is shined on the PV array, so that the MOSFET is turned on and the voltage or current generated by the PV array is provided to the load. The MOSFET solution requires additional circuitry to provide the turn-on voltage for the gate of the MOSFET.

FIG. 4B illustrates a PV device 200 with a PV array and a transistor formed on a WBS 202, which is a monolithic substrate. The PV device 200 includes a first silicon substrate 100, an oxide 91, and a second silicon substrate 101 that are stacked in order. The PV array includes a plurality of cells PV1, PV2, PV3, etc. The transistor is a MOSFET M12 and is integrated with the additional circuit elements for turn on and off operations. When light shines on the PV array (see FIG. 4A), the MOSFET is also turned on to provide electrical energy to the load. MOSFET M12 is separated from the cells by isolation structures 113 and 114.

Since the MOSFET is integrated with the PV array on a monolithic substrate or WBS, the resultant die is small and can be packaged as a single, discrete device. The package includes plastic encapsulation that may be transparent. The PV device has two pins according to one embodiment.

Such a discrete product that contains small, packaged PV devices with high voltage output enables the operation of portable devices with an off line battery chargers—namely using light energy to charge up the battery. Accordingly, the present embodiment enables wireless devices or instruments to be mounted anywhere without a power line to power it since the power is obtained from light via the high efficiency PV devices.

One feature of the present embodiment is the flexibility to add more integrated circuit elements to the PV device formed on an SOI substrate. An isolated island of the SOI PV die may be incorporated to other analog or digital control circuits in an integrated form as part of the overall PV die. In the present embodiment, a transistor connects the PV array to the load. The transistor, e.g., MOSFET, is used to conduct current from the PV array to the load. The load can be a battery, a capacitor, or any electronic device that is charged or needs electrical power from the PV solar array.

FIG. 5 illustrates a cross-sectional view of a PV device 500 with a transistor provided on a monolithic substrate according to one embodiment of the present invention. The PV device includes a first substrate 502, an oxide layer 504, and a second substrate 506. In the present embodiment, the first and second substrate are bonded to each other.

A plurality of cells or tubs 512-518 are defined using the second substrate 506. The second substrate is n-type silicon. The cells are separated from each other by trenches 522. The trenches are filled with oxide and un-doped polysilicon, as explained in FIG. 2. The width of the opening of the trench is at least 5,000 angstroms. In one implementation, the width or opening is about 2 microns or more, or about 3 microns or more, or about microns or more, or about 5 microns or more.

The cells or tubs 512, 514 and 518 are used to define PV cells or solar cells. The cell or tub 516 is used to define a transistor 519, e.g., MOSFET. Each tub may be used to define other types electronic components since it provides an electrically isolated platform. The PV cells are defined in an n-type tubs, so that the NMOS transistor can be formed since NMOS transistors generally provide better performance characteristics than PMOS transistors for power device application. In another implementation, however, the tubs may be p-type regions.

Each PV cell 512, 514, and 518 includes a p-type region 534, which is p+ region. Each PV cell also includes an n+ region that is used to couple the cell to another cell. Conductive interconnects 540 and 542 are used for this purpose. The interconnect 540 connects the cells 512 and 514. The interconnect 542 connects the cell 514 and others (not shown) to the transistor 519 of the cell 516 and provides the necessary voltage to turn on the transistor 519.

The transistor 519 includes a gate 550, a source/drain 552, and a drain/source 554. The gate 550 is coupled to the PV cell 514 to receive the turn-on voltage via the interconnect 542. The source and drain regions provide current to flow from the PV array to the load when the gate is turned on, thereby storing or powering the load. The source and drain regions are formed in p− regions 556 and 558 in the present implementation.

FIG. 6 describes the circuit diagram of the PV array with a MOSFET 602 (also denoted as “M1”) as the “SR” according to one embodiment of the present invention. A first or main PV array 604 (also denoted as “PV1”) is used to convert light or solar energy for a load 608. A second PV array 606 is coupled to the gate of the MOSFET 602 and is used to apply turn-on voltage to the transistor 602. The first and second PV arrays are coupled at a node 610 in the present embodiment. The MOSFET is configured to have a low threshold voltage Vₜₕ in the present embodiment, so that a fewer PV cells would be needed to turn it on. It is desirable, for example, to have the MOSFET turn-on array to provide a voltage equal or greater than the threshold voltage Vₜₕ plus 3v. As an example, a MOSFET with an on-resistance, Rₒₙ of 10 ohms, with a current from the PV array of 30 microamperes will drop only 300 microvolts, which is 1000 times less than a typical Schottky diode that drops 300 millivots. The MOSFET M1 and the second PV array 606 are incorporated to the main PV array, as shown in FIG. 5.

FIG. 7 the circuit diagram of a PV device is coupled to a load 702 according to another embodiment of this invention. The PV device includes a charge pump circuit 704 rather than a second PV array to turn on a transistor 706 (also denoted as “M2”). The charge pump circuit is designed to provide a voltage greater than the Vth of the MOSFET to insure its turn on and provide a low-resistance current path from a PV array 708 (or “PV1”) to the load 702.

FIG. 8 illustrates a charge pump circuit 802 that corresponds to the pump 704 according to one embodiment. The charge pump 802 includes a capacitor C2, a diode D4 and at least two MOS switches S2 and S3 to provide the necessary turn-on voltage to the MOSFET M2. In the present implementation, the pump 704 is a CMOS based and is defined in one or more cells or tubs of the WBS and is part of the monolithic substrate whereon the main PV array is defined.

As illustrated in FIGS. 7 and 8, the charge pump is provided between nodes 710, 711 and 712. The charge pump is configured to turn on the MOSFET M2 synchronous with the light activated output of the main PV array.

FIG. 9 illustrates a PV device having a plurality of PV arrays 902, 904, and 906 according to one embodiment of the present invention. The PV array are coupled to outputs 940, 941, and 943. The PV arrays are defined on a monolithic die with multiple voltage outputs on a SOI structure having a plurality of tubs. The PV device also includes a plurality of transistors 912, 914, and 916. Each transistor is provided between the PV array and output.

The PV arrays 902 and 904 are coupled to each other via nodes 930 and 931 in the illustrated embodiment. These two arrays may be electrically isolated in other embodiments. The PV array 906 is electrically isolated from PV arrays 902 and 904. Each output may output different or same voltage according to desired applications.

The PV-SOI devices above are encapsulated in plastic packages according to one embodiment. In another embodiment, the devices are encapsulated in hermetic packages with transparent plastic or glass windows. In another embodiment, the PV SOI die is assembled in an LED package with the LED die next to it. In many application for electronic products, it has been desirable to have an LED as an indicator lamp, or a source of light. In some of these applications, it is desirable also to include the PV device to provide electrical charging power. In such applications, the PV SOI die is provided next to the LED die and packaged as a singled packaged device to reduce the cost of an extra package.

The integrated package feature above uses the LED package for dual purposes: one is to diffuse and spread the LED light out of the package; and another is to concentrate the external incident light into the package onto the PV die. Furthermore, part of the LED emitted light that is not transmitted out and trapped inside the package is converted back to electrical power by the PV die inside that package. Other combinations of co-packaged LEDs and PV SOI dice can be implemented by persons trained in the art according to the teachings of the embodiments described herein.

In one embodiment, to implement the integrated device above, any of the available LED (also referred to optoelectronic packages). One can use discrete, for the single voltage output, and IC packages for the multiple voltages output, in surface mount or for insertion mounting techniques, i.e. SO, or SOT, SIP or DIP forms ( These are standard names of some of the available packages, SO & SOT designate discrete surface mount packages. SIP-single in line package, DIP-dual in line package).

FIG. 10A illustrates a packaged PV device 1000 having a PV device or die 1004 according to one embodiment of the present invention. The packaged PV device 1000 includes a plastic or hermetic package with a transparent plastic or glass window 1002. The window allows light, represented as arrows 1001, to fall on the PV die 1004. The die converts the light to electrical power. In particular, FIG. 10A illustrates the use of the PV die in a package for use as an LED. This LED has a dome or lens 1003 to focus light onto the die. The electrical power is output through pins 1005 and 1006 that are coupled to the contact pads of the die by a wire 1007. This method of light concentration increases the power output of the encapsulated integrated PV.

FIG. 10B illustrates a discrete packaged PV device 1010 with an integrated concentrating lens 1012 and a PV device or die 1014 according to another embodiment of the present invention. The electrical power is output through pins 1015 and 1016 that extends outwardly on the opposite sides of the packaged device. The backside 1018 of the package device may be polymer or ceramic materials.

FIG. 10C illustrates a metal-can-hermetic PV device 1020 according to yet another embodiment of the present invention. A PV die 1021 is mounted inside a metal housing 1021. A curved lens 1024 concentrates the light onto the die 1021. Pins 1025 and 1026 are used to output the electrical power resulting from the light.

FIG. 10D illustrates yet another feature of the invention, where a PV die 1032 and an LED die 1034 are packaged within in an LED package 1030. In many applications for electronic products, it is desirable to have an LED as an indicator lamp or a light source. In some of these applications, it is desirable also to include a PV die to provide electrical charging power. In such applications, a PV die is assembled next to the LED die within the same package of the LED.

This feature uses the LED package for dual purposes. One is to diffuse and spread the LED light out of the package, and another is to concentrate the external incident light into the package and onto the PV die. Furthermore, part of the LED emitted light that is not transmitted out (but is trapped inside the package) is converted back to electrical power by the PV die inside that package. Other combinations of co-packaged LEDs and PV dice can be implemented according to the application needs.

The embodiment described above may be implemented using any of the available LED or optoelectronic packages. A discrete or IC packages may be used in surface mount technology or insertion mount technology, e.g., in SO, or SOT, SIP or DIP standard packages. SO and SOT relate to discrete surface mount packages. SIP refers tot single in line package, and DIP refers to dual in line package.

The present embodiment provides one or more transparent areas above the LED and PV die or dice for multi-chip features.

The present invention has been described in terms of specific embodiment. Accordingly, the present invention may be implemented in other ways. For example, a plurality of PV arrays are formed in two or more dice and enclosed in the same package. The scope of the present invention should be interpreted based on the appended claims.

1. A photovoltaic (PV) device, comprising:
a silicon-on-insulator (SOI) substrate including a first substrate, a second substrate, and an insulating layer provided between the first and second substrates;
a plurality of tubs defined using the first substrate, each tub being isolated from an adjacent tub using the insulation layer and an isolation structure;
a first PV array including a plurality of PV cells to generate a first voltage when light is shined on the first PV array;
a second PV array including a plurality of PV cells to generate a second voltage when the light is shined on the second PV array;
a transistor defined on one of the tubs and coupled to the first and second PV arrays,
wherein the first PV array is configured to provide a turn-on voltage to the transistor when the second PV array is generating the second voltage.

2. The device of claim 1, further comprising:
an encapsulation enclosing the first PV array, second PV array, and transistor, the encapsulation having a transparent portion to enable light to shine on at least one of the first and second PV arrays.

3. The device of claim 1 wherein each tub includes a body of n-type region and the transistor is a NMOSFET.

4. The device of claim 1, wherein each tub includes a body of p-type region and the transistor is a PMOSFET.

5. The device of claim 1, wherein each of the tubs is separated from an adjacent tub by a trench with a width that is at least 2 microns.

6. The device of claim 5, wherein the isolation structure is defined within the trench, the isolation structure including an oxide layer and a polysilicon plug formed on the oxide layer.

7. The device of claim 1, wherein the device is a discrete packaged device.

8. The device of claim 7, wherein the device has no more than two leads extending outwardly from the package of the device.

9. The device of claim 7, wherein the device has no more than six leads extending outwardly from the package of the device.

10. The device of claim 1, wherein each PV cell of the first and second PV arrays is defined in a corresponding one of the plurality of tubs.

11. A packaged photovoltaic (PV) device, comprising:
a structure including a first substrate, a second substrate, and an insulating layer provided between the first and second substrates;
a plurality of tubs defined using the first substrate, each tub being isolated from an adjacent tub using the insulation layer and an isolation structure extending orthogonal to the insulating layer;
a first PV array including a plurality of PV cells to generate a first voltage when the light is shined on the first PV array;
a component defined on at least one tub and coupled to the first PV array, the component including a first node coupled to the first PV array and a second node configured to be coupled to a load; and
a packaged enclosing the first PV array and the component,
wherein the component is configured to be turned on when the first PV array is generating the first voltage, so that the generated first voltage can be transferred from the first node to the second node,
wherein each PV cell of the first PV array is defined in a corresponding one of the plurality of tubs.

12. The device of claim 11, further comprising a charge pump coupling the first PV array to the component provide a turn on voltage to the component, the component being a transistor.

13. The device of 12, further comprising:
an LED formed within the package.

14. The device of claim 12, wherein the structure is a wafer-bonded structure.

15. The device of claim 11, further comprising:
a second PV array including a plurality of PV cells to generate a second voltage when light is shined on the second PV array, the second PV array being configured to apply the second voltage to the component to turn on the component.

16. A method for forming a photovoltaic (PV) device, the method comprising:
providing a structure including a first substrate, a second substrate, and an insulating layer provided between the first and second substrates;
forming a plurality of tubs using the first substrate, each tub being isolated from an adjacent tub using the insulation layer and an isolation structure extending orthogonal to the insulation layer;
forming a first PV array including a plurality of PV cells to generate a first voltage when light is shined on the first PV array;
forming a second PV array including a plurality of PV cells to generate a second voltage when the light is shined on the second PV array;
forming a transistor defined on at least one tub and coupled to the first and second PV arrays; and
enclosing the first and second PV arrays and the transistor in a package.
